(19) United States
(12) Patent Application Publication
(10) Pub. No.: US 2025/0293192 A1
(43) Pub. Date: Sep. 18, 2025

(54) FILM-FORM ADHESIVE, ADHESIVE FILM, INTEGRATED DICING/DIE BONDING FILM, AND METHOD FOR MANUFACTURING SEMICONDUCTOR DEVICE

(71) Applicant: Resonac Corporation, Minato-ku, Tokyo (JP)

(72) Inventors: Michiko KAYA, Minato-ku, Tokyo (JP); Shota AOYAGI, Minato-ku, Tokyo (JP); Noriyuki NAKAYAMA, Minato-ku, Tokyo (JP); Mikiko KIMURA, Minato-ku, Tokyo (JP)

(21) Appl. No.: 18/860,696

(22) PCT Filed: Aug. 9, 2023
(86) PCT No.: PCT/JP2023/029170

§ 371 Date: Oct. 28, 2024

(30) Foreign Application Priority Data
Sep. 14, 2022 (JP) 2022-146281

(51) Int. Cl. H01L 23/00; H01L 21/683; H01L 21/78

(52) U.S. Cl. CPC H01L 24/29; H01L 21/6836; H01L 21/78; H01L 24/32; H01L 24/83; H01L 24/94; H01L 2221/68327; H01L 2224/29291; H01L 2224/32245; H01L 2224/83191; H01L 2224/83203; H01L 2224/83862; H01L 2224/94

(57) ABSTRACT

A film-like adhesive containing a thermosetting resin component; and a filler, in which the film-like adhesive has a single layer structure including a first surface and a second surface, and has a region in a vicinity of the first surface, the region in which a content rate of the filler decreases in a direction from the second surface toward the first surface.

### TECHNICAL FIELD

The present disclosure relates to a film-like adhesive, an adhesive film, a dicing/die-bonding integrated film, and a method for manufacturing a semiconductor device.

### BACKGROUND ART

In recent years, with the increase in functionality and speed of smartphones, tablet PCs, and the like, semiconductor packages used therefor are required to be further reduced in size, increased in capacity, increased in speed, reduced in thickness, and the like. In a wafer used in such semiconductor packages, further miniaturization of wiring is progressing, and a chip tends to be further thinned when the semiconductor package is assembled.

Under such a tendency, particularly in the fields of DRAM and NAND flash memories, a problem that an operation defect occurs due to an extremely small amount of heavy metal ions such as copper ions has started to become apparent. When heavy metal ions come into contact with silicon crystals, the heavy metal ions may diffuse in the crystal and reach a circuit surface, thereby causing an operation defect. From the viewpoint of preventing occurrence of an operation defect, in assembly of a semiconductor package, it is common to perform gettering processing for trapping heavy metal ions on a silicon wafer so that the heavy metal ions attached to the silicon wafer do not diffuse to a circuit surface.

As the gettering processing, for example, a method that provides a gettering layer inside the wafer (intrinsic gettering, hereinafter referred to as “IG”) and a method that provides a gettering layer on a back surface of the wafer (extrinsic gettering, hereinafter referred to as “EG”) are mainly used. However, in the IG, the thickness of the gettering layer that can be formed inside has decreased as the chip has become thinner, and the effect is not sufficient. In addition, in the EG, since minute cracks are formed on the back surface of the wafer, deflective strength of the chip decreases. Therefore, there is a problem that it is difficult to perform excessive gettering processing particularly in an ultrathin wafer that is difficult to handle. Under such circumstances, it has been studied to impart a gettering function for capturing heavy metal ions to a resin film (an adhesive film used in a manufacturing process of a semiconductor device), more specifically, a film-like adhesive (die-bonding film) used for adhesion between a chip and a substrate or between chips (see, for example, Patent Literatures 1 and 2).

### CITATION LIST

### Patent Literature

Patent Literature 1: Japanese Unexamined Patent Publication No. 2011-213878

Patent Literature 2: Japanese Unexamined Patent Publication No. 2012-241157

### SUMMARY OF INVENTION

### Technical Problem

However, the film-like adhesive in the related art is not sufficient in suppressing defects associated with movement of copper ions in the adhesive, and there is still room for improvement. The present disclosure provides a film-like adhesive having a barrier function of preventing movement of heavy metal ions, for example, copper ions, and an adhesive film including the same. The present disclosure also provides a dicing/die-bonding integrated film including a film-like adhesive as a first adhesive layer, and a method for manufacturing a semiconductor device using the same.

### Solution to Problem

A film-like adhesive according to a first aspect of the present disclosure is a film-like adhesive formed of a resin composition having thermosetting properties and containing a filler, the film-like adhesive having a single layer structure including a first surface and a second surface, in which the film-like adhesive has a region in the vicinity of the first surface, the region in which the content rate of the filler decreases from the second surface side toward the first surface side.

A film-like adhesive according to a second aspect of the present disclosure is a film-like adhesive formed of a resin composition having thermosetting properties and containing a filler, the film-like adhesive having a single layer structure including a first surface and a second surface, in which when the film-like adhesive is cured by heating, the film-like adhesive after thermal curing has a region in the vicinity of the first surface, the region in which the content rate of the filler decreases from the second surface side toward the first surface side. A state in which the film-like adhesive is cured by heating means a state in which a reaction rate is 90% or more in a general method for evaluating the degree of curing by comparing calorific values before and after reaction by DSC (thermal differential scanning calorimeter, for example, Thermo Plus 2manufactured by Rigaku Corporation). To cure the film-like adhesive, for example, heating may be performed at 170° C. for three hours.

The film-like adhesive having the above region has a barrier function of preventing movement of heavy metal ions. The reason is not necessarily clear, but the present inventors assume as follows. That is, the fact that the content rate of the filler in the region positioned in vicinity of the first surface is relatively low means that, in other words, in the vicinity of the first surface, a region having a relatively high content rate of the resin component (resin-rich region) is locally formed in a thickness direction, and meanwhile, is formed with a continuous spread in a plane direction. Since the region is denser than other regions, it is assumed that the region exhibits the barrier function of preventing movement of heavy metal ions.

An adhesive film according to the present disclosure includes the film-like adhesive according to the first or second aspect and a base film in contact with the second surface of the film-like adhesive. A dicing/die-bonding integrated film according to the present disclosure includes a first adhesive layer configured of the film-like adhesive according to the first or second aspect, a second adhesive layer in contact with the second surface of the film-like adhesive, a first adhesive layer in contact with the second adhesive layer, and a base film in contact with the first adhesive layer in which the dicing/die-bonding integrated film includes the first adhesive layer, the second adhesive layer, and the base film in this order.

A method for manufacturing a semiconductor device according to the present disclosure includes: attaching a wafer onto the first surface of the film-like adhesive (first adhesive layer) in the dicing/die-bonding integrated film; singulating the wafer and the film-like adhesive into a plurality of adhesive piece-attached chips; picking up the adhesive piece-attached chip from the second adhesive layer; and bonding the chip onto a substrate or another chip via the adhesive piece.

### Advantageous Effects of Invention

The present disclosure provides a film-like adhesive having a barrier function of preventing movement of heavy metal ions, for example, copper ions, and an adhesive film including the same. Also, the present disclosure provides a dicing/die-bonding integrated film including a film-like adhesive as a first adhesive layer, and a method for manufacturing a semiconductor device using the same.

### BRIEF DESCRIPTION OF DRAWINGS

FIG. 1 is a cross-sectional view schematically illustrating one embodiment of a film-like adhesive according to the present disclosure.

FIG. 2 is a cross-sectional view schematically illustrating an example of an adhesive film including the film-like adhesive illustrated in FIG. 1.

FIG. 3 is a cross-sectional view schematically illustrating one embodiment of a dicing/die-bonding integrated film according to the present disclosure.

FIG. 4 is a cross-sectional view schematically illustrating an example of a semiconductor device.

FIG. 5 is a cross-sectional view schematically illustrating another example of the semiconductor device.

FIG. 6 is a cross-sectional view schematically illustrating another embodiment of the film-like adhesive according to the present disclosure.

### DESCRIPTION OF EMBODIMENTS

Hereinafter, embodiments of the present disclosure are described with appropriate reference to the drawings. However, the present invention is not limited to the following embodiments. In the following embodiments, the components (including steps and the like) are not essential unless otherwise specified. The sizes of the components in the drawings are conceptual, and the relative size relationship between the components is not limited to that illustrated in the drawings.

The same applies to numerical values and ranges thereof in the present specification, and the present invention is not limited thereto. In the present specification, a numerical range indicated using “to” indicates a range including numerical values described before and after “to” as a minimum value and a maximum value, respectively. In numerical ranges described in stages in the present specification, an upper limit value or a lower limit value described in one numerical range may be replaced with an upper limit value or a lower limit value of another numerical range described in stages. In addition, in a numerical range described in the present specification, an upper limit value or a lower limit value of the numerical range may be replaced with a value shown in examples. In the present specification, (meth)acrylate means acrylate or methacrylate corresponding thereto. The same applies to other similar expressions such as a (meth)acryloyl group and a (meth)acrylic copolymer.

### Film-like Adhesive

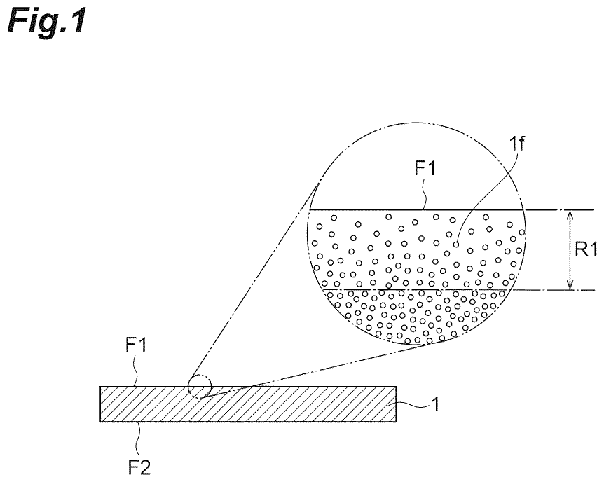

FIG. 1 is a cross-sectional view schematically illustrating a film-like adhesive according to the present disclosure. A film-like adhesive 1 illustrated in the drawing has a single-layer structure formed of a resin composition having thermosetting properties and containing a filler. The thickness of the film-like adhesive 1 may be 50 μm or less and may be, for example, 40 μm or less, 30 μm or less, 20 μm or less, or 10 μm or less. When the thickness of the film-like adhesive 1 is 50 μm or less, the distance between a semiconductor element and a support member on which the semiconductor element is mounted becomes short such that defects due to heavy metal ions tend to easily occur, and thus the effect of the present invention is easily obtained. The lower limit of the thickness of the film-like adhesive 1 is not particularly limited but is, for example, 2 μm or more. When the thickness of the film-like adhesive 1 is 2 μm or more, a film having a better appearance tends to be easily obtained.

The film-like adhesive 1 has, in vicinity of a first surface F1, a region R1 (a region of which the thickness is indicated by an arrow in the enlarged view illustrated in FIG. 1) in which the content rate of a filler decreases from a second surface F2 side toward the first surface F1 side. The region R1 is formed of a plurality of fillers 1f and a resin component. In the region R1, the content rate of the filler may be continuously reduced or stepwise reduced. The region R1 plays a role of preventing movement of heavy metal ions. That is, the fact that the content rate of the filler in the region R1 positioned in vicinity of the first surface F1 is relatively low means that, in other words, in vicinity of the first surface F1, a region having a relatively high content rate of the resin component (resin-rich region) is locally formed in a thickness direction, and meanwhile, is formed with a continuous spread in a plane direction. Since the region R1 is denser than other regions, it is assumed that the region R1 has a barrier function of preventing movement of heavy metal ions.

The region R1 according to the present embodiment varies depending on the thickness of the film-like adhesive 1, but is at a position where the depth from the first surface F1 is shallower than the position of 2 μm. In other words, “vicinity of the first surface F1” in the present embodiment means a region where the depth from the first surface F1 is shallower than the position of 2 μm. Note that as long as the region R1 exists in the vicinity of the first surface F1, for example, a region having a high content rate of the filler may locally exist on the first surface F1.

The existence and thickness of the region R1 can be confirmed, for example, by causing a slurry including abrasive grains to collide with the first surface F1 at a high speed and measuring the wear rate, or may be confirmed by measurement with a rigid body pendulum type physical property tester. In particular, the method for measuring the wear rate by causing the slurry including abrasive grains to collide at a high speed can sufficiently reduce the influence of heat on the film-like adhesive 1. The existence and thickness of the region R1 may be confirmed after the film-like adhesive 1 is cured by heating. Specifically, a film-like adhesive after thermal curing and a film-like adhesive obtained by physically removing the vicinity of the first surface F1 of the film-like adhesive after thermal curing are prepared, the crystal of ATR is changed, and the measurement is performed while changing the penetration depth, whereby the composition difference between both can be grasped. The existence and thickness of the region R1 can also be confirmed by observing a cross section of the film-like adhesive.

The thickness of the region R1 is, for example, 0.05 to 2 μm and may be 0.1 to 1.5 μm or 0.3 to 1 μm. When the thickness of the region R1 is 0.05 μm or more, the region RI tends to be able to play a role of preventing movement of heavy metal ions, and when the thickness of the region R1 is 0.1 μm or more, the region R1 tends to be able to sufficiently play a role of preventing movement of heavy metal ions. Meanwhile, when the thickness of the region R1 is 2 μm or less, the handleability of the film-like adhesive 1 tends to be easily maintained. The ratio of the thickness of the region R1 with respect to the total thickness of the film-like adhesive 1 is, for example, 0.3 to 25% and may be 1 to 20% or 3 to 15%. When the ratio is 0.3% or more, the region R1 tends to be able to play a role of preventing movement of heavy metal ions, and when the ratio is 1% or more, the region R1 tends to be able to sufficiently play a role of preventing movement of heavy metal ions. Meanwhile, when the ratio is 25% or less, an effect that the mechanical strength of the film-like adhesive 1 can be maintained is exhibited.

The film-like adhesive 1 is formed of an adhesive composition containing a thermosetting resin component (A) and a filler (B). The film-like adhesive 1 may pass through a semi-cured (B stage) state and may be in a cured (C stage) state after a curing treatment. In one embodiment, the thermosetting resin component (A) may include a thermosetting resin (A1), a curing agent (A2), and an elastomer (A3).

Component (A1): Thermosetting Resin

The component (A1) may be epoxy resin from the viewpoint of adhesiveness. The epoxy resin can be used without particular limitation as long as the epoxy resin has an epoxy group in the molecule. Examples of the epoxy resin include bisphenol A-type epoxy resin, bisphenol F-type epoxy resin, bisphenol S-type epoxy resin, phenol novolac-type epoxy resin, cresol novolac-type epoxy resin, bisphenol A novolac-type epoxy resin, bisphenol F novolac-type epoxy resin, stilbene-type epoxy resin, triazine skeleton-containing epoxy resin, fluorene skeleton-containing epoxy resin, triphenol methane-type epoxy resin, biphenyl-type epoxy resin, xylylene-type epoxy resin, biphenyl aralkyl-type epoxy resin, naphthalene-type epoxy resin, polyfunctional phenols, and a diglycidyl ether compound of polycyclic aromatics such as anthracene. The examples may be used singly or in combination of two or more kinds thereof. Among the resins, the component (A1) may be cresol novolac-type epoxy resin, phenol novolac-type epoxy resin, bisphenol F-type epoxy resin, or bisphenol A-type epoxy resin from the viewpoint of tackiness, flexibility, and the like of the film.

The epoxy equivalent of the epoxy resin is not particularly limited but may be 90 to 300 g/eq or 110 to 290 g/eq. When the epoxy equivalent of the epoxy resin is in such a range, fluidity tends to be able to be secured while the bulk strength of the film-like adhesive is maintained.

Component (A2): Curing Agent

The component (A2) may be phenol resin that can serve as a curing agent for the epoxy resin. The phenol resin can be used without particular limitation as long as the phenol resin has a phenolic hydroxyl group in the molecule. Examples of the phenol resin include novolac-type phenol resin obtained by condensation or co-condensation of phenols such as phenol, cresol, resorcin, catechol, bisphenol A, bisphenol F, phenylphenol, and aminophenol and/or naphthols such as α-naphthol, β-naphthol, and dihydroxynaphthalene with a compound having an aldehyde group such as formaldehyde under an acidic catalyst, and phenol aralkyl resin and naphthol aralkyl resin synthesized from phenols and/or naphthols such as allylated bisphenol A, allylated bisphenol F, allylated naphthalenediol, phenol novolac, and phenol and/or dimethoxyparaxylene or bis(methoxymethyl) biphenyl. The examples may be used singly or in combination of two or more kinds thereof. Among the resins, the phenol resin may be novolac-type phenolic resin or naphthol aralkyl resin.

The hydroxyl group equivalent of the phenol resin may be 70 g/eq or more or 70 to 300 g/eq. When the hydroxyl group equivalent of the phenol resin is 70 g/eq or more, the storage elastic modulus of the film tends to be further improved, and when the hydroxyl group equivalent of the phenol resin is 300 g/eq or less, defects due to foaming, generation of outgas, and the like can be prevented.

The ratio of the epoxy equivalent of the epoxy resin to the hydroxyl group equivalent of the phenol resin (epoxy equivalent of epoxy resin/hydroxyl group equivalent of phenol resin) may be 0.30/0.70 to 0.70/0.30, 0.35/0.65 to 0.65/0.35, 0.40/0.60 to 0.60/0.40, or 0.45/0.55 to 0.55/0.45 from the viewpoint of curability. When the equivalent ratio thereof is 0.30/0.70 or more, more sufficient curability tends to be obtained. When the equivalent ratio is 0.70/0.30 or less, the viscosity can be prevented from becoming too high, and thus more sufficient fluidity can be obtained.

The total content of the component (A1) and the component (A2) may be 5 to 50 parts by mass, 10 to 40 parts by mass, or 15 to 30 parts by mass with respect to 100 parts by mass of the total mass of the component (A). When the total content of the component (A1) and the component (A2) is 5 parts by mass or more, the elastic modulus tends to be improved by crosslinking. When the total content of the component (A1) and the component (A2) is 50 parts by mass or less, film handleability tends to be able to be maintained.

Component (A3): Elastomer

The component (A3) may be an acrylic rubber having a constituent unit derived from (meth)acrylic acid ester as a main component. The content of the constituent unit derived from the (meth)acrylic acid ester in the component (A3) may be, for example, 70 mass % or more, 80 mass % or more, or 90 mass % or more with respect to the total amount of the constituent units. The acrylic rubber may include a constituent unit derived from (meth)acrylic acid ester having a crosslinkable functional group such as an epoxy group, an alcoholic or phenolic hydroxyl group, or a carboxyl group. In addition, the component (A3) may include a constituent unit derived from acrylonitrile, but the component (A3) may not include a constituent unit derived from acrylonitrile because permeation of heavy metal ions in the adhesive can be further prevented and the embedding properties are more excellent.

The glass transition temperature (Tg) of the component (A3) may be −50 to 50° C. or −30 to 30° C. When the Tg of the component (A3) is −50° C. or higher, the flexibility of the adhesive tends to be able to be prevented from becoming too high. As a result, the film-like adhesive is easily cut at the time of wafer dicing, and generation of burrs can be prevented. When the Tg of the component (A3) is 50° C. or lower, a decrease in flexibility of the adhesive tends to be able to be prevented. As a result, when the film-like adhesive is attached to a wafer, voids tend to be easily embedded sufficiently. In addition, it is possible to prevent chipping at the time of dicing due to a decrease in adhesion of the wafer. Here, the glass transition temperature (Tg) means a value measured by using DSC (thermal differential scanning calorimeter) (for example, Thermo Plus 2 manufactured by Rigaku Corporation).

The weight average molecular weight (Mw) of the component (A3) may be 100,000 to 3,000,000 or 200,000 to 2,000,000. When the Mw of the component (A3) is in such a range, film formability, strength in the film form, flexibility, tackiness, and the like can be appropriately controlled, reflowability is excellent, and embeddability can be improved. Here, the Mw means a value measured by gel permeation chromatography (GPC) and converted by using a calibration curve by standard polystyrene.

Examples of commercially available products of the component (A3) include an SG-P3 improved product and SG-80H (both manufactured by Nagase ChemteX Corporation).

The total content of the component (A3) may be 50 to 95 parts by mass, 60 to 90 parts by mass, or 70 to 85 parts by mass with respect to 100 parts by mass of the total mass of the component (A). When the content of the component (A3) is in such a range, movement (permeation) of heavy metal ions in the adhesive tends to be able to be more sufficiently prevented. When the component (A3) is an acrylic rubber, the content rate of the acrylic rubber is, for example, 50 to 85 mass % and may be 55 to 80 mass % or 60 to 80 mass %, with respect to the total mass of the adhesive composition. When the content rate is 50 mass % or more, an effect that the region R1 is easily formed is exhibited and meanwhile, when the content rate is 85 mass % or less, an effect that workability in manufacturing of the film-like adhesive 1 is easily maintained is exhibited.

In another embodiment, the thermosetting resin component (A) may include an elastomer having a crosslinkable functional group such as an epoxy group, an alcoholic or phenolic hydroxyl group, or a carboxyl group, and a curing agent capable of reacting with the crosslinkable functional group. Examples of the combination of the elastomer having a crosslinkable functional group and the curing agent capable of reacting with the crosslinkable functional group include a combination of an acrylic rubber having an epoxy group and phenol resin.

Component (B): Filler

The component (B) may be either an inorganic filler or an organic filler. Examples of the inorganic filler include aluminum hydroxide, magnesium hydroxide, calcium carbonate, magnesium carbonate, calcium silicate, magnesium silicate, calcium oxide, magnesium oxide, aluminum oxide, aluminum nitride, aluminum borate whisker, boron nitride, and silica. The examples may be used singly or in combination of two or more kinds thereof. Among the resins, the component (B) may be silica from the viewpoint of adjusting melt viscosity. Examples of the organic filler include carbon, a rubber-based filler, a silicone-based fine particle, a polyamide fine particle, and a polyimide fine particle. The shape of the component (B) is not particularly limited but may be spherical.

The average particle diameter of the component (B) may be 0.01 to 1 μm, 0.01 to 0.8 μm, or 0.03 to 0.5 μm from the viewpoint of fluidity. Here, the average particle diameter means a value obtained by conversion from the BET specific surface area.

The content of the component (B) may be 0.1 to 50 parts by mass, 0.1 to 30 parts by mass, or 0.1 to 20 parts by mass with respect to 100 parts by mass of the total mass of the component (A). The content rate of the component (B) is, for example, 3 to 55 mass % and may be 5 to 50 mass % or 7 to 40 mass % with respect to the total mass of the adhesive composition. When the content rate is 3 mass % or more, an effect that the mechanical strength of the film-like adhesive 1 is maintained is exhibited, and meanwhile, when the content rate is 55 mass % or less, an effect that a good appearance of the film-like adhesive 1 is maintained is exhibited.

The film-like adhesive (adhesive composition) may further contain a coupling agent (C), a curing accelerator (D), and the like.

Component (C): Coupling Agent

The component (C) may be a silane coupling agent. Examples of the silane coupling agent include γ-ureidopropyltriethoxysilane, γ-mercaptopropyltrimethoxysilane, 3-phenylaminopropyltrimethoxysilane, and 3-(2-aminoethyl) aminopropyltrimethoxysilane. The examples may be used singly or in combination of two or more kinds thereof.

Component (D): Curing Accelerator

The component (D) is not particularly limited, and those generally used can be used. Examples of the component (D) include imidazoles and derivatives thereof, an organophosphorus compound, secondary amines, tertiary amines, and quaternary ammonium salts. The examples may be used singly or in combination of two or more kinds thereof. Among the examples, the component (D) may be imidazoles and derivatives thereof from the viewpoint of reactivity. Examples of the imidazoles include 2-methylimidazole, 1-benzyl-2-methylimidazole, 1-cyanoethyl-2 phenylimidazole, and 1-cyanoethyl-2 methylimidazole. The examples may be used singly or in combination of two or more kinds thereof.

The film-like adhesive 1 may further contain other components. Examples of other components include a leveling agent, a pigment, an ion scavenger, and an antioxidant. The contents of the component (C), the component (D), and other components may be 0 to 30 parts by mass with respect to 100 parts by mass of the total mass of the component (A).

### Method for Manufacturing Film-like Adhesive

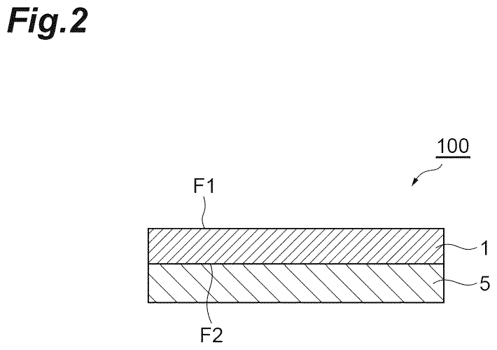

The film-like adhesive 1 can be formed by applying an adhesive composition to a support film. When a varnish (adhesive varnish) of the adhesive composition is used, the film-like adhesive 1 can be obtained through the steps of mixing the component (A), the component (B), and other components that are added as necessary in a solvent, mixing or kneading the mixed liquid to prepare an adhesive varnish, applying the adhesive varnish to a support film 5, and removing the solvent by drying. An adhesive sheet 100 illustrated in FIG. 2 is configured with a support film 5 and the film-like adhesive 1 provided on the surface of the support film 5.

When the film-like adhesive 1 is formed from the coating film of the adhesive varnish, the region RI can be formed in the vicinity of the first surface F1 by removing the solvent by drying while applying air to the surface of the coating film. The speed of wind flowing in parallel with the upper surface of the coating film is, for example, 3 to 20 m/sec. When the speed is 3 m/sec or more, the drying of the component (A) on the surface of the coating film to which wind is applied is promoted, and an effect that the region R1 having a sufficient thickness is easily formed in the vicinity of the first surface F1 of the film-like adhesive 1 is exhibited, and meanwhile, when the speed is 20 m/sec or less, an effect that the appearance of the surface of the coating film is easily maintained is obtained.

The drying temperature of the adhesive varnish is, for example, 25 to 150° C. and may be 60 to 145° C. or 70 to 140° C. When the drying temperature is 70° C. or higher, an effect that productivity is easily maintained is exhibited, and meanwhile, when the drying temperature is 150° C. or lower, an effect of easily preventing appearance defects is exhibited.

The support film 5 is not particularly limited as long as the support film 5 can withstand heating and drying described above and may be, for example, a polyester film, a polypropylene film, a polyethylene terephthalate film, a polyimide film, a polyetherimide film, a polyether naphthalate film, or a polymethylpentene film. The support film 5 may be a multilayer film obtained by combining two or more kinds or may have a surface treated with a silicone-based or silica-based release agent or the like. The thickness of the support film 5 may be, for example, 10 to 200 μm or 20 to 170 μm.

Mixing or kneading can be performed by using a disperser such as an ordinary stirrer, a mixer, a three-roll, or a ball mill and appropriately combining such dispersers. The solvent used for preparing the adhesive varnish is not limited as long as the solvent can uniformly dissolve, knead, or disperse components and conventionally known solvents can be used. Examples of such a solvent include ketone-based solvents such as acetone, methyl ethyl ketone, methyl isobutyl ketone, and cyclohexanone, dimethylformamide, dimethylacetamide, N-methyl-2-pyrrolidone, toluene, and xylene. The solvent may be methyl ethyl ketone, cyclohexanone, or the like from the viewpoint of high drying speed and low price. As a method of applying the adhesive varnish to the support film, a known method can be used, and examples thereof include a knife coating method, a roll coating method, a spray coating method, a gravure coating method, a bar coating method, and a curtain coating method.

The surface tension of the adhesive varnish is, for example, 27 to 44 mN/m and may be 28 to 40 mN/m or 28 to 38 mN/m. When the value is in the above range, an effect that it is easy to manufacture a film having a good appearance and manufacturing workability is easily maintained is exhibited. Note that the surface tension of the adhesive varnish means a value measured by a hanging drop method under conditions of a room temperature of 22 to 28° C. and a humidity of 40 to 60% without wind. The surface tension of the adhesive varnish can be adjusted, for example, by blending a leveling agent into the adhesive varnish.

### Dicing/Die-Bonding Integrated Film

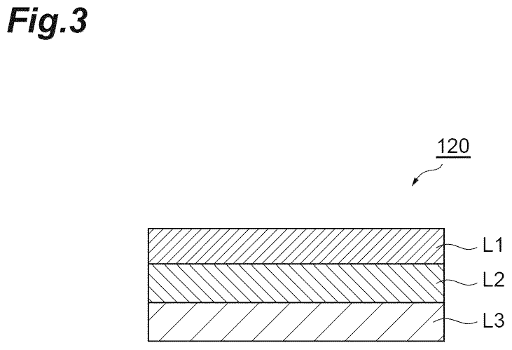

FIG. 3 is a schematic cross-sectional view illustrating a dicing/die-bonding integrated film including the film-like adhesive 1. A dicing/die-bonding integrated film 120 illustrated in the drawing includes a first adhesive layer L1 formed of the film-like adhesive 1, a second adhesive layer L2 in contact with the second surface F2 of the film-like adhesive 1, and a base film L3 in contact with the second adhesive layer L2 in this order. A dicing tape is formed of the second adhesive layer L2 and the base film L3.

### Semiconductor Device

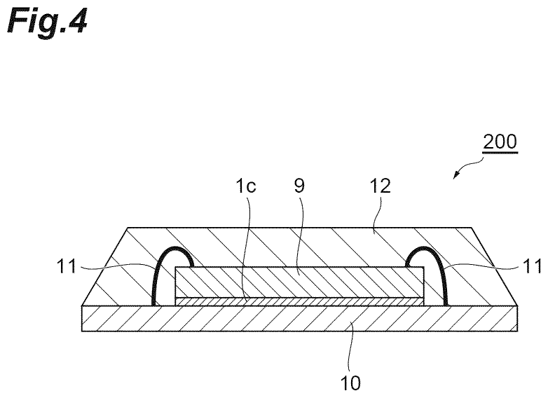

For example, a semiconductor device illustrated in FIG. 4 can be manufactured by using the dicing/die-bonding integrated film 120. A semiconductor device 200 illustrated in FIG. 4 includes a semiconductor chip 9, a support member 10 on which the semiconductor chip 9 is mounted, and a cured product 1c of an adhesive piece provided between the semiconductor chip 9 and the support member 10. The adhesive piece is obtained by singulating the film-like adhesive 1 into pieces. The cured product 1c adheres the semiconductor chip 9 and the support member 10. A connection terminal (not illustrated) of the semiconductor chip 9 is electrically connected to an external connection terminal (not illustrated) via a wire 11 and is sealed by a sealing material 12.

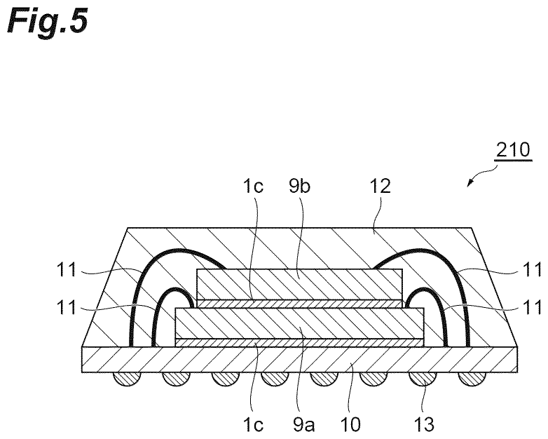

For example, a semiconductor device illustrated in FIG. 5 can be manufactured by using the dicing/die-bonding integrated film 120. In a semiconductor device 210 illustrated in FIG. 5, a first-stage semiconductor chip 9a is adhered to the support member 10 by the cured product 1c, and a second-stage semiconductor chip 9b is further adhered onto the first-stage semiconductor chip 9a by the cured product 1c. Connection terminals (not illustrated) of the first-stage semiconductor chip 9a and the second-stage semiconductor chip 9b are electrically connected to the external connection terminal via the wire 11 and sealed by the sealing material 12. A terminal 13 is formed on a lower surface of the support member 10.

### Method for Manufacturing Semiconductor Device

The semiconductor devices 200 and 210 are manufactured through, for example, the following steps.

Attaching a wafer onto the first surface F1 of the first adhesive layer L1 (film-like adhesive) in the dicing/die-bonding integrated film 120.

Singulating the wafer and the first adhesive layer L1 (film-like adhesive) into a plurality of adhesive piece-attached chips.

Pcking up the adhesive piece-attached chip from the second adhesive layer L2.

Bonding the semiconductor chip onto a substrate or another semiconductor chip via the adhesive piece.

The semiconductor devices 200 and 210 are obtained, for example, by interposing an adhesive piece between the semiconductor chip and the support member or between the semiconductor chip and the semiconductor chip, adhering both by thermocompression bonding, and then passing through a wire bonding step, a sealing step with a sealing material, a heating and melting step including reflow by solder, and the like as necessary. The heating temperature in the thermocompression bonding step is usually 20 to 250° C., the load is usually 0.1 to 200 N, and the heating time is usually 0.1 to 300 seconds.

The support member may include a member made of copper. Since the semiconductor devices 200 and 210 are manufactured by using the film-like adhesive 1 having a barrier function of preventing movement of heavy metal ions (for example, copper ions), even when a member made of copper is used as a component of the semiconductor device, an influence of copper ions generated from the component can be reduced, and occurrence of electrical defects caused by the copper ions can be sufficiently prevented. Here, examples of the member made of copper include a lead frame, wiring, a wire, a heat dissipation material, and the like, and regardless of which member copper is used for, the influence of copper ions can be reduced.

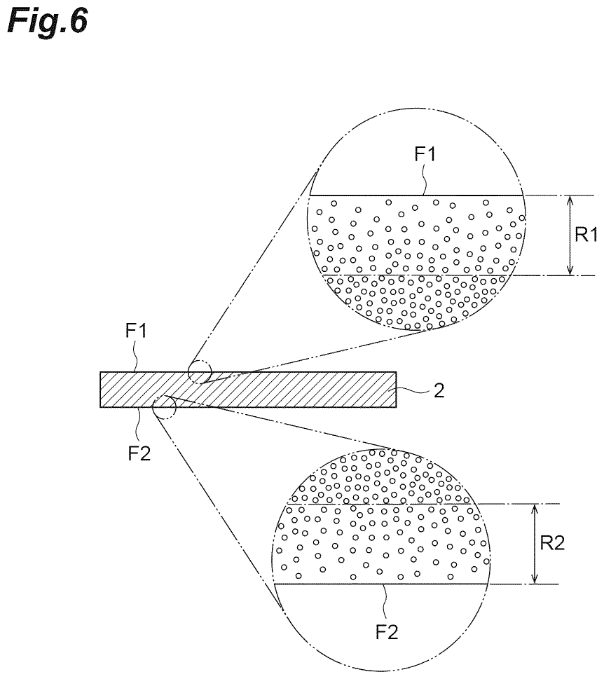

Although the embodiments of the present disclosure are described in detail above, the present invention is not limited to the above embodiments. For example, in the above embodiment, the aspect in which the region R1 is formed in the vicinity of the first surface F1 is exemplified, and as illustrated in FIG. 6, a region R2 similar to the region R1 may be formed in the vicinity of the second surface F2. A film-like adhesive 2 illustrated in the same drawing has the same configuration as the film-like adhesive 1 except that the film-like adhesive 2 further includes the region R2 in the vicinity of the second surface F2, the region in which the content rate of the filler decreases from the first surface F1 side toward the second surface F2 side. The region R2 is at a position where the depth from the second surface F2 is shallower than the position of 2 μm. In other words, “vicinity of the second surface F2” means a region where the depth from the second surface F2 is shallower than the position of 2 μm. Note that as long as the region R2 exists in the vicinity of the second surface F2, and for example, a region having a high content rate of the filler may locally exist on the second surface F2.

The thickness of the film-like adhesive 2 may be 50 μm or less and may be, for example, 40 μm or less, 30 μm, 20 μm or less, or 10 μm or less. When the thickness of the film-like adhesive 2 is 50 μm or less, the distance between a semiconductor element and a support member on which the semiconductor element is mounted becomes short such that defects due to heavy metal ions tend to easily occur, and thus the effect of the present invention is easily obtained. The lower limit of the thickness of the film-like adhesive 2 is not particularly limited but can be set to, for example, 2 μm or more. When the thickness of the film-like adhesive 2 is 2 μm or more, a film having a better appearance tends to be easily obtained. The thickness of the region R2 is, for example, 0.05 to 2 μm and may be 0.1 to 1.5 μm or 0.3 to 1 μm. When the thickness of the region R2 is 0.05 μm or more, the region R2 tends to be able to play a role of preventing movement of heavy metal ions, and when the thickness of the region R2 is 0.1 μm or more, the region R2 tends to be able to sufficiently play a role of preventing movement of heavy metal ions. Meanwhile, when the thickness of the region R2 is 2 μm or less, the effect that the handleability of the film-like adhesive 2 tends to be easily maintained is exhibited. The ratio of the thickness of the region R2 with respect to the total thickness of the film-like adhesive 2 is, for example, 0.3 to 25% and may be 1 to 20% or 3 to 15%. When the ratio is 0.3% or more, the region R2 tends to be able to play a role of preventing movement of copper ions. Furthermore, when the ratio is 1% or more, the region R2 tends to be able to sufficiently play a role of preventing movement of heavy metal ions. Meanwhile, when the ratio is 25% or less, an effect that the mechanical strength of the film-like adhesive 2 can be maintained is exhibited.

The present disclosure relates to the following matters.

[1] A film-like adhesive formed of a resin composition having thermosetting properties and containing a filler, the film-like adhesive having a single layer structure comprising a first surface and a second surface,
wherein the film-like adhesive has a region in a vicinity of the first surface, the region in which a content rate of the filler decreases from the second surface side toward the first surface side.

[2] A film-like adhesive formed of a resin composition having thermosetting properties and containing a filler, the film-like adhesive having a single layer structure comprising a first surface and a second surface,
wherein when the film-like adhesive is cured by heating, the film-like adhesive after thermal curing has a region in a vicinity of the first surface, the region in which a content rate of the filler decreases from the second surface side toward the first surface side.

[3] The film-like adhesive according to [1] or [2], in which a thickness of the region is 2 μm or less.

[4] The film-like adhesive according to any one of [1] to [3], in which a ratio of a thickness of the region with respect to a total thickness of the film-like adhesive is 0.3 to 25%.

[5] The film-like adhesive according to any one of [1] to [4], in which the region is positioned at a position where a depth from the first surface is shallower than a position of 2 μm.

[6] The film-like adhesive according to any one of [1] to [5], in which a content rate of the filler is 3 to 55 mass % with respect to a total mass of the resin composition.

[7] The film-like adhesive according to any one of [1] to [6], in which the resin composition contains an acrylic rubber, and a content rate of the acrylic rubber is 50 to 85 mass % with respect to a total mass of the resin composition.

[8] An adhesive film including:
the film-like adhesive according to any one of [1] to [7]; and
a base film in contact with the second surface of the film-like adhesive.

[9] A dicing/die-bonding integrated film including:
a first adhesive layer formed of the film-like adhesive according to any one of [1] to [7];
a second adhesive layer in contact with the second surface of the film-like adhesive; and
a base film in contact with the second adhesive layer, in which the dicing/die-bonding integrated film comprises the first adhesive layer, the second adhesive layer, and the base film in this order.

A method for manufacturing a semiconductor device, the method including:
attaching a wafer onto the first surface of the film-like adhesive in the dicing/die-bonding integrated film according to [9];
singulating the wafer and the film-like adhesive into a plurality of adhesive piece-attached chips;
picking up the adhesive piece-attached chip from the second adhesive layer; and
bonding the chip onto a substrate or another chip via the adhesive piece.

### EXAMPLES

Hereinafter, the present disclosure is specifically described based on examples and comparative examples. Note that the present invention is not limited to the following examples.

### Examples 1 to 6 and Comparative Example 1

### [Manufacturing of Film-like Adhesive]

### <Preparation of Adhesive Varnish>

Acrylic rubber solutions shown in Tables 1 and 2 were used as adhesive varnishes. Note that the numerical values relating to compositions shown in Tables 1 and 2 mean parts by mass of the solid content of the acrylic rubber solution.

Epoxy Resin
N-500P-10 (Trade name, manufactured by DIC Corporation, o-cresol novolac-type epoxy resin, epoxy equivalent: 203 g/eq)

Curing Agent (Phenol Resin)
MEH-7800M (Trade name, manufactured by Meiwa Chemical Co. Ltd., phenol novolac-type phenol resin, hydroxyl group equivalent: 175 g/eq, softening point: 61 to 90° C.)
PSM-4326 (Trade name, manufactured by Gun Ei Chemical Industry Co., Ltd., softening point: 120° C.)

Acrylic Rubber
SG-P3 Improved Product 1 (Trade name, manufactured by Nagase ChemteX Corporation)
Acrylic rubber of SG-P3 Improved Product 2 (Trade name, manufactured by Nagase ChemteX Corporation) excluding a constituent unit derived from acrylonitrile.

Inorganic Filler
R972 (Trade name, manufactured by Nippon Aerosil Co., Ltd., silica particles, average particle diameter: 0.016 μm)
SC2050-HLG (Trade name, manufactured by Admatechs Company Limited, silica filler dispersion, average particle diameter: 0.50 μm)

Coupling Agent
Z-6119 (Trade name, manufactured by Dow Toray Co., Ltd., 3-ureidopropyltriethoxysilane)
A-189 (Trade name, manufactured by Nitto Unicar Company

Limited, γ-mercaptopropyltrimethoxysilane)

Leveling Agent
BYK-333: Polyether-modified polydimethylsiloxane (manufactured by BYK Japan KK)
BYK-325N: Polyether-modified polymethylalkylsiloxane (manufactured by BYK Japan KK)

Curing Accelerator
2PZ-CN (Trade name, manufactured by Shikoku Kasei Holdings Corporation, 1-cyanoethyl-2-phenylimidazole)

### <Manufacturing of Film-like Adhesive>

### Examples 1 to 6 and Comparative Example 1

Adhesive varnishes having compositions shown in Tables 1 and 2 were filtered through a 100 mesh filter and vacuum-defoamed. The surface tension (hanging drop method) of the obtained adhesive varnish was 36 mN/m. A polyethylene terephthalate (PET) film (thickness: 38 μm) subjected to a release treatment was prepared as a base film, and the adhesive varnish after vacuum defoaming was applied onto the PET film. The application amount of the adhesive varnish was adjusted so that the thickness after drying was 20 μm. The applied adhesive varnish was dried under conditions shown in Tables 1 and 2 to obtain a film-like adhesive in a B-stage state. In the table, “wind” “Yes” means that the adhesive varnish was dried under the condition that the speed of the wind flowing in parallel with the surface of the coating film was 3 m/s or more, and “wind” “No” means that the adhesive varnish was dried under the condition that the speed of the wind flowing in parallel with the surface of the coating film was substantially 0 m/sec or more.

### Comparative Example 2

A film-like adhesive was prepared in the same manner as in Example 1, and then a surface layer on a surface (first surface) side of the film-like adhesive was removed. That is, a range to a depth of about 0.6 μm from the surface of the film-like adhesive was removed by using a plasma processing system PX-250 (manufactured by Nippon Sanso Holdings Corporation) so that the resin-rich region was removed.

### [Evaluation of Effect of Preventing Copper Ion Permeation]

### <Preparation of Liquid A>

2.0 g of anhydrous copper (II) sulfate was dissolved in 1020 g of distilled water and stirred until copper sulfate was completely dissolved to prepare a copper sulfate aqueous solution having a copper ion concentration of 500 mg/kg in terms of Cu element. The obtained copper sulfate aqueous solution was set as Liquid A.

### <Preparation of Liquid B>

1.0 g of anhydrous sodium sulfate was dissolved in 1000 g of distilled water, and the mixture was stirred until the sodium sulfate was completely dissolved. To the obtained solution, 1000 g of N-methyl-2-pyrrolidone (NMP) was further added, and the mixture was stirred. Thereafter, air cooling was performed until the temperature reached room temperature to obtain a sodium sulfate aqueous solution. The obtained solution was set as Liquid B.

### <Measurement of Copper Ion Permeation Time>

Each of the film-like adhesive s (thickness: 10 μm) of examples and comparative examples manufactured above was cured and then cut into a circular shape having a diameter of about 3 cm. Next, two silicone packing sheets having a thickness of 1.5 mm, an outer diameter of about 3 cm, and an inner diameter of 1.8 cm were prepared. The film-like adhesive cut out into a circular shape was interposed between two silicone packing sheets, and the silicone packing sheets were interposed between flange portions of two glass cells having a volume of 50 mL and fixed with a rubber band.

Next, 50 g of Liquid A was injected into one glass cell, and then 50 g of Liquid B was injected into the other glass cell. As a carbon electrode, Mars Carbon (manufactured by STAEDTLER SE, 92 mm/130 mm) was inserted into each cell. With Liquid A side as an anode and Liquid B side as a cathode, the anode and a direct current power supply (manufactured by A&D Company, Limited, DC power supply AD-9723D) were connected. In addition, the cathode and the DC power supply were connected in series via an ammeter (manufactured by Sanwa Electric Instrument Co., Ltd., Degital multimeter PC-720M). A voltage was applied at an applied voltage of 24.0 V at room temperature, and the measurement of the current value was started after the voltage was applied. The measurement time was up to 500 minutes, and the rise time of the current value was defined as the copper ion permeation time. The rise time was set as time when the current value reached 1.0 μA. In the evaluation, it can be said that the slower the rise time of the current value, the more the copper ion permeation is prevented. Evaluation was performed according to the following criteria. Results are shown in Tables 1 and 2.

A: The copper ion permeation time is 100 minutes or more. B: The copper ion permeation time is 60 minutes or more and less than 100 minutes.

C: The copper ion permeation time is less than 60 minutes.

TABLE 1

| | | Example 1 | Example 2 | Example 3 | Example 4 |
|---|---|---|---|---|---|
| Composition | N-500P-10 | 10.0 | 10.0 | 10.0 | 10.0 |
| (parts by mass) | MEH-7800M | 10.0 | 10.0 | 10.0 | 10.0 |
| | PSM-4326 | — | — | — | — |
| | SG-P3 Improved Product 1 | 70.0 | 70.0 | 70.0 | 70.0 |
| | SC2050-HLG | — | — | — | — |
| | R972 | 8.0 | 8.0 | 8.0 | 8.0 |
| | z-6119 | 1.0 | 1.0 | 1.0 | 1.0 |
| | A-189 | 0.50 | 0.50 | 0.50 | 0.50 |
| | BYK-333 | — | — | 0.50 | — |
| | BYK-325N | — | — | — | 0.50 |
| | 2PZ-CN | 0.02 | 0.02 | 0.02 | 0.02 |

| | | | | |
|---|---|---|---|---|
| Varnish surface tension (mN/m) | 36 | 36 | 28 | 31 |
| Wind | Yes | Yes | Yes | Yes |
| Surface removal treatment | Not | Not | Not | Not |
| | performed | performed | performed | performed |
| Drying temperature (° C.) | 105 | 130 | 130 | 130 |
| Effect of suppressing permeation of copper ions | B | B | A | A |

TABLE 2

| | | Example | Example | Comparative | Comparative |
|---|---|---|---|---|---|
| | | 5 | 6 | Example 1 | Example 2 |
| Composition | N-500P-10 | 11.0 | 10.0 | 10.0 | 10.0 |
| (parts by mass) | MEH-7800M | — | 10.0 | 10.0 | 10.0 |
| | PSM-4326 | 6.0 | — | — | — |
| | SG-P3 Improved Product 1 | — | 70.0 | 70.0 | 70.0 |
| | SG-P3 Improved Product 2 | 73.0 | — | — | — |
| | SC2050-HLG | 8.0 | — | — | — |
| | R972 | — | 8.0 | 8.0 | 8.0 |
| | z-6119 | 1.0 | 1.0 | 1.0 | 1.0 |
| | A-189 | 0.50 | 0.50 | 0.50 | 0.50 |
| | BYK-333 | — | — | — | — |
| | BYK-325N | — | — | — | — |
| | 2PZ-CN | 0.02 | 0.02 | 0.02 | 0.02 |

| | | | | |
|---|---|---|---|---|
| Varnish surface tension (mN/m) | 37 | 36 | 36 | 36 |
| Wind | Yes | Yes | No | Yes |
| Surface removal treatment | Not | Not | Not | Performed |
| | performed | performed | performed | |
| Drying temperature (° C.) | 130 | 25 | 25 | 105 |
| Effect of suppressing permeation of copper ions | A | B | C | C |

### REFERENCE SIGNS LIST

1, 2: Film-like adhesive, 1c: Cured product, 5: Support film, 9, 9a, 9b: Semiconductor chip, 10: Support member, 11: Wire, 12: Sealing material, 13: Terminal, 100: Adhesive sheet, 120: Dicing/die-bonding integrated film, F1: First surface, F2: Second surface, L1: First adhesive layer (film-like adhesive), L2: Second adhesive layer, L3: Base film, R1, R2: Region

1. A film-like adhesive comprising:
a thermosetting resin component; and
a filler,
wherein the film-like adhesive has a single layer structure comprising a first surface and a second surface, and
wherein the film-like adhesive has a region in a vicinity of the first surface, the region in which a content rate of the filler decreases in a direction from the second surface toward the first surface.

2. A film-like adhesive comprising:
a thermosetting resin component; and
a filler,
wherein the film-like adhesive has a single layer structure comprising a first surface and a second surface, and
wherein the film-like adhesive, after being cured by heating, has a region in a vicinity of the first surface, the region in which a content rate of the filler decreases in a direction from the second surface toward the first surface.

3. The film-like adhesive according to claim 1, wherein a thickness of the region is 2 μm or less.

4. The film-like adhesive according to claim 1, wherein a ratio of a thickness of the region with respect to a total thickness of the film-like adhesive is 0.3 to 25%.

5. The film-like adhesive according to claim 1, wherein the region is positioned at a position where a depth from the first surface is shallower than a position of 2 μm.

6. The film-like adhesive according to claim 1, wherein a content rate of the filler is 3 to 55 mass % with respect to a total mass of the film-like adhesive.

7. The film-like adhesive according to claim 1, wherein the film-like adhesive comprises an acrylic rubber, and a content rate of the acrylic rubber is 50 to 85 mass % with respect to a total mass of the film-like adhesive.

8. An adhesive film comprising:
the film-like adhesive according to claim 1; and
a base film in contact with the second surface of the film-like adhesive.

9. A dicing/die-bonding integrated film comprising:
a first adhesive layer formed of the film-like adhesive according to claim 1;
a second adhesive layer in contact with the second surface of the film-like adhesive; and
a base film in contact with the second adhesive layer,
wherein the dicing/die-bonding integrated film comprises second adhesive layer located between the first adhesive layer and the base film.

10. A method for manufacturing a semiconductor device, the method comprising:
attaching a wafer onto the first surface of the film-like adhesive in the dicing/die-bonding integrated film according to claim 9;
singulating the wafer and the film-like adhesive to obtain a plurality of adhesive piece-attached chips, each comprising a chip obtained by singulating the wafer, and an adhesive piece obtained by singulating the film-like adhesive in contact with the chip;
picking up the adhesive piece-attached chips from the second adhesive layer; and
bonding the chip onto a substrate or another chip via the adhesive piece.

11. The method according to claim 10, wherein a first adhesive piece-attached chip is picked up from the second adhesive layer, the first adhesive piece-attached chip comprising a first chip and a first adhesive piece in contact with the first chip, and the first chip is bonded onto the substrate via the first adhesive piece, and
wherein a second adhesive piece-attached chip is picked up from the second adhesive layer, the second adhesive piece-attached chip comprising a second chip and a second adhesive piece in contact with the second chip, and the second chip is bonded onto the first chip on the substrate via the second adhesive piece.

12. The film-like adhesive according to claim 2, wherein a thickness of the region is 2 μm or less.

13. The film-like adhesive according to claim 2, wherein a ratio of a thickness of the region with respect to a total thickness of the film-like adhesive is 0.3 to 25%.

14. The film-like adhesive according to claim 2, wherein the region is positioned at a position where a depth from the first surface is shallower than a position of 2 μm.

15. The film-like adhesive according to claim 2, wherein a content rate of the filler is 3 to 55 mass % with respect to a total mass of the film-like adhesive resin composition.

16. The film-like adhesive according to claim 2, wherein the film-like adhesive comprises an acrylic rubber, and a content rate of the acrylic rubber is 50 to 85 mass % with respect to a total mass of the film-like adhesive.

17. An adhesive film comprising:
the film-like adhesive according to claim 2; and
a base film in contact with the second surface of the film-like adhesive.

18. A dicing/die-bonding integrated film comprising:
a first adhesive layer formed of the film-like adhesive according to claim 2;
a second adhesive layer in contact with the second surface of the film-like adhesive; and
a base film in contact with the second adhesive layer,
wherein the dicing/die-bonding integrated film comprises the second adhesive layer located between the first adhesive layer and the base film.

19. A method for manufacturing a semiconductor device, the method comprising:
attaching a wafer onto the first surface of the film-like adhesive in the dicing/die-bonding integrated film according to claim 18;
singulating the wafer and the film-like adhesive to obtain a plurality of adhesive piece-attached chips, each comprising a chip obtained by singulating the wafer, and an adhesive piece obtained by singulating the film-like adhesive in contact with the chip;
picking up the adhesive piece-attached chip from the second adhesive layer; and
bonding the chip onto a substrate or another chip via the adhesive piece.

20. The method according to claim 19, wherein a first adhesive piece-attached chip is picked up from the second adhesive layer, the first adhesive piece-attached chip comprising a first chip and a first adhesive piece in contact with the first chip, and the first chip is bonded onto the substrate via the first adhesive piece, and
wherein a second adhesive piece-attached chip is picked up from the second adhesive layer, the second adhesive piece-attached chip comprising a second chip and a second adhesive piece in contact with the second chip, and the second chip is bonded onto the first chip on the substrate via the second adhesive piece.
